(19) United States
(12) Patent Application Publication
(10) Pub. No.: US 2026/0123296 A1
(43) Pub. Date: Apr. 30, 2026

(54) NON-VOLATILE MEMORY DEVICE AND METHOD OF FORMING THE SAME

(71) Applicant: Nanyang Technological University, Singapore (SG)

(72) Inventors: Yuanmin Du, Singapore (SG); Wen Siang Lew, Singapore (SG); Putu Andhita Dananjaya, Singapore (SG); Weng Hong Lai, Singapore (SG)

(21) Appl. No.: 19/117,064

(22) PCT Filed: Oct. 3, 2023
(86) PCT No.: PCT/SG2023/050658

§ 371 Date: Mar. 30, 2025

(30) Foreign Application Priority Data
Oct. 7, 2022 (SG) 10202251306M
Nov. 25, 2022 (SG) 10202260203T

(51) Int. Cl. H10N 70/00; H10B 63/00; H10N 70/20

(52) U.S. Cl. CPC H10N 70/8833; H10B 63/20; H10N 70/021; H10N 70/24; H10N 70/841

(57) ABSTRACT

Various embodiments may relate to a non-volatile memory device. The non-volatile memory device may include a first electrode and a second electrode. The non-volatile memory device may additionally include a switching stacked arrangement between the first electrode and the second electrode, and an oxygen scavenger layer between the switching stacked arrangement and the second electrode. The non-volatile memory device may additionally include a diffusion barrier layer between the oxygen scavenger layer and the second electrode. The switching stacked arrangement may include alternating tunneling barrier layers and active layers. A first tunneling barrier layer of the tunneling barrier layers may be in physical contact with the first electrode. A last active layer of the active layers may be in physical contact with the oxygen scavenger layer. A bandgap of each of the tunneling barrier layers may be greater than a bandgap of each of the active layers.

### CROSS-REFERENCE TO RELATED APPLICATION

This application claims the benefit of priority of Singapore application No. 10202251306M filed Oct. 7, 2022 and Singapore application No. 10202260203T filed Nov. 25, 2022, the contents of them being hereby incorporated by reference in their entirety for all purposes.

### TECHNICAL FIELD

Various embodiments of this disclosure may relate to a non-volatile memory. Various embodiments of this disclosure may relate to a method of forming a non-volatile memory.

### BACKGROUND

The demand for highly integrated semiconductor devices has led to the down-scaling of a memory device. Traditional memories, such as dynamic random access memory (DRAM), static random access memory (SRAM) and flash memory, face challenges in such a miniaturization progress. In an attempt to advance the size reduction, new non-volatile memories have been developed, and resistive random access memory (RRAM) is one of them. RRAM uses semiconducting or insulating materials (typically metal oxides) as a recording layer to store different resistance states in a non-volatile manner. The device can be switched between different resistance states with the electrical field applied, and the states can be maintained during the whole retention time.

Resistive switching elements normally use an electroforming process to form conductive filaments (or pathways) to prepare a memory device for use. The resistance switching between two stable resistance stables by an electrical field may be controlled through the generation and destruction of the conductive filaments. The electrical resistance may be increased to a high resistance state (HRS) when the conductive filaments are fractured and decreased to a low resistance state (LRS) when the conducive filaments are connected. Non-destructive read operations can be performed to ascertain the written electrical resistance state stored in a memory cell. Using this property, a memory-storage function can be achieved.

The nature (size, shape, content, number etc.) of the conductive filaments is not only critical to a stable switching process, but also important for uniformity improvement. For this purpose, different stack configurations have been developed.

It is desired to improve the performance of the resistive switching devices that have been developed, to meet the requirements for a non-volatile memory in the down-scaling trend.

### SUMMARY

Various embodiments may relate to a non-volatile memory device. The non-volatile memory device may include a first electrode. The non-volatile memory device may also include a second electrode. The non-volatile memory device may additionally include a switching stacked arrangement between the first electrode and the second electrode. The non-volatile memory device may further include an oxygen scavenger layer between the switching stacked arrangement and the second electrode. The non-volatile memory device may additionally include a diffusion barrier layer between the oxygen scavenger layer and the second electrode. The switching stacked arrangement may include alternating tunneling barrier layers and active layers. A first tunneling barrier layer of the tunneling barrier layers may be in physical contact with the first electrode. A last active layer of the active layers may be in physical contact with the oxygen scavenger layer. A bandgap of each of the tunneling barrier layers may be greater than a bandgap of each of the active layers.

Various embodiments may relate to a method of forming a non-volatile memory device. The method may include forming a first electrode. The method may also include forming a second electrode. The method may further include forming a switching stacked arrangement between the first electrode and the second electrode. The method may additionally include forming an oxygen scavenger layer between the switching stacked arrangement and the second electrode. The method may also include forming a diffusion barrier layer between the oxygen scavenger layer and the second electrode. The switching stacked arrangement may include alternating tunneling barrier layers and active layers. A first tunneling barrier layer of the tunneling barrier layers may be in physical contact with the first electrode. A last active layer of the active layers may be in physical contact with the oxygen scavenger layer. A bandgap of the tunneling barrier layers may be greater than a bandgap of the active layers.

### BRIEF DESCRIPTION OF THE DRAWINGS

In the drawings, like reference characters generally refer to the same parts throughout the different views. The drawings are not necessarily drawn to scale, emphasis instead generally being placed upon illustrating the principles of various embodiments. In the following description, various embodiments of the invention are described with reference to the following drawings.

FIG. 1 is a general illustration of a non-volatile memory device according to various embodiments.

FIG. 2 is a general illustration of a method of forming a non-volatile memory device according to various embodiments.

FIG. 3 shows a cross-sectional schematic of a non-volatile memory device according to various embodiments.

FIG. 4 shows a cross-sectional schematic of another non-volatile memory device according to various embodiments.

FIG. 5 shows a cross-sectional schematic of another non-volatile memory device according to various embodiments.

FIG. 6A shows a cross-sectional schematic illustrating an operational mechanism based on the non-volatile memory device shown in FIG. 3 according to various embodiments.

FIG. 6B shows another cross-sectional schematic illustrating the operational mechanism based on the non-volatile memory device shown in FIG. 3 according to various embodiments.

FIG. 7 shows a plot of current (in Amperes or A) as a function of voltage (in volts or V) illustrating the voltage-current characteristics of the electroforming process of a non-volatile memory device according to various embodiments.

FIG. 8 shows a plot of current (in Amperes or A) as a function of voltage (in volts or V) of the non-volatile memory device according to various embodiments after the electroforming process described in FIG. 7.

FIG. 9 shows a plot of resistance (in ohms or (2) as a function of cycles illustrating a voltage pulse endurance test results of the non-volatile memory device used for the plots shown in

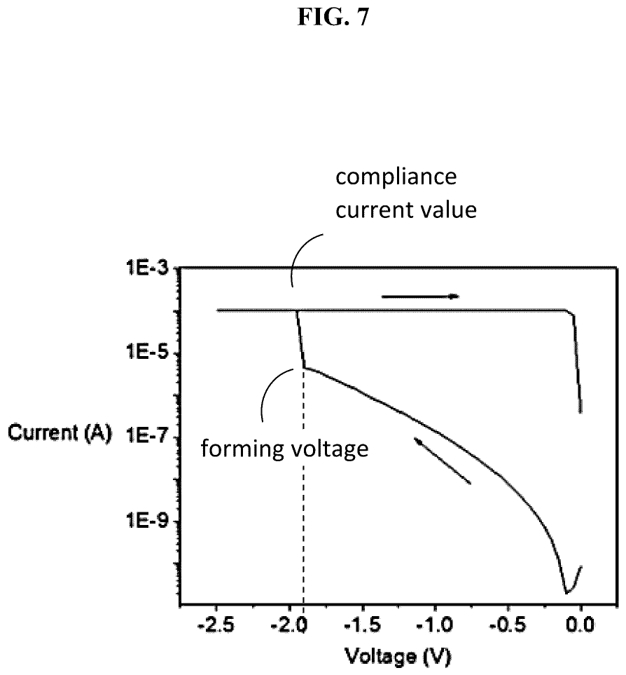

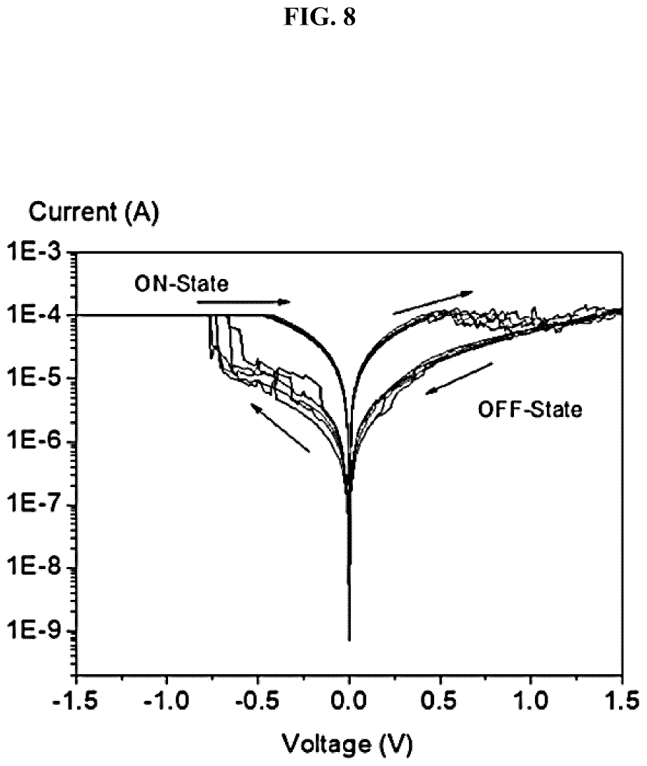

FIGS. 7-8 according to various embodiments.

FIG. 10 shows a flow chart of forming a non-volatile memory device according to various embodiments.

FIG. 11 is a general illustration of a non-volatile memory device according to various embodiments.

FIG. 12 is a general illustration of a method of forming a non-volatile memory device according to various embodiments.

FIG. 13 shows a cross-sectional schematic of a non-volatile memory device according to various embodiments.

FIG. 14A shows a cross-sectional schematic of another non-volatile memory device according to various embodiments.

FIG. 14B shows the switching stacked arrangement with a triple-layered structure including three active layers according to various embodiments.

FIG. 15A shows a cross-sectional schematic illustrating an operational mechanism based on the non-volatile memory device shown in FIG. 13 according to various embodiments.

FIG. 15B shows another cross-sectional schematic illustrating the operational mechanism based on the non-volatile memory device shown in FIG. 13 according to various embodiments.

FIG. 16A shows a cross-sectional schematic of a non-volatile memory device without an iridium oxide layer.

FIG. 16B shows a cross-sectional schematic of a non-volatile memory device with an iridium oxide layer according to various embodiments.

FIG. 17 shows a plot of current (in Amperes or A) as a function of voltage (in volts or V) illustrating the voltage-current characteristics of the electroforming process of a non-volatile memory device according to various embodiments.

FIG. 18 shows a plot of current (in Amperes or A) as a function of voltage (in volts or V) of the non-volatile memory device according to various embodiments after the electroforming process described in FIG. 17.

FIG. 19 shows a plot of resistance (in ohms or Ω) as a function of cycles illustrating a voltage pulse endurance test results of the non-volatile memory device used for the plots shown in FIGS. 17-18 according to various embodiments.

FIG. 20 shows a flow chart of forming a non-volatile memory device according to various embodiments.

FIG. 21 shows a flow chart of forming a non-volatile memory device according to various embodiments.

### DESCRIPTION

The following detailed description refers to the accompanying drawings that show, by way of illustration, specific details and embodiments in which the invention may be practiced. These embodiments are described in sufficient detail to enable those skilled in the art to practice the invention. Other embodiments may be utilized and structural, logical, and electrical changes may be made without departing from the scope of the invention. The various embodiments are not necessarily mutually exclusive, as some embodiments can be combined with one or more other embodiments to form new embodiments.

Features that are described in the context of an embodiment may correspondingly be applicable to the same or similar features in the other embodiments. Features that are described in the context of an embodiment may correspondingly be applicable to the other embodiments, even if not explicitly described in these other embodiments. Furthermore, additions and/or combinations and/or alternatives as described for a feature in the context of an embodiment may correspondingly be applicable to the same or similar feature in the other embodiments.

In the context of various embodiments, the articles “a”, “an” and “the” as used with regard to a feature or element include a reference to one or more of the features or elements.

In the context of various embodiments, the term “about” or “approximately” as applied to a numeric value encompasses the exact value and a reasonable variance, e.g., within 10% of the specified value.

As used herein, the term “and/or” includes any and all combinations of one or more of the associated listed items.

By “comprising” it is meant including, but not limited to, whatever follows the word “comprising”. Thus, use of the term “comprising” indicates that the listed elements are required or mandatory, but that other elements are optional and may or may not be present.

By “consisting of” is meant including, and limited to, whatever follows the phrase “consisting of”. Thus, the phrase “consisting of” indicates that the listed elements are required or mandatory, and that no other elements may be present.

Embodiments described in the context of one of the non-volatile memory device are analogously valid for the other non-volatile memory devices. Similarly, embodiments described in the context of a method are analogously valid for a non-volatile memory device, and vice versa.

Various embodiments may relate to an improved non-volatile memory device (or simply non-volatile memory). Various embodiments may relate to a non-volatile memory device integrated with current complementary metal oxide semiconductor (CMOS) technology. Various embodiments may relate to a non-volatile memory device that has low voltages, stable resistive switching, and simple fabrication processes.

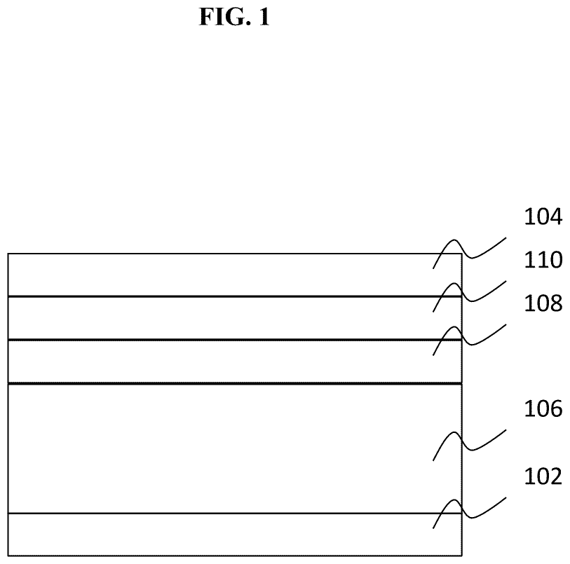

FIG. 1 is a general illustration of a non-volatile memory device according to various embodiments. The non-volatile memory device may include a first electrode 102. The non-volatile memory device may also include a second electrode 104. The non-volatile memory device may additionally include a switching stacked arrangement 106 between the first electrode 102 and the second electrode 104. The non-volatile memory device may further include an oxygen scavenger layer 108 between the switching stacked arrangement 106 and the second electrode 104. The non-volatile memory device may additionally include a diffusion barrier layer 110 between the oxygen scavenger layer 108 and the second electrode 104. The switching stacked arrangement 106 may include alternating tunneling barrier layers and active layers. A first tunneling barrier layer of the tunneling barrier layers may be in physical contact with the first electrode 102. A last active layer of the active layers may be in physical contact with the oxygen scavenger layer 108. A bandgap of each of the tunneling barrier layers may be greater than a bandgap of each of the active layers.

In other words, the non-volatile memory device may include a first electrode 102, a switching stacked arrangement 106 on or over the first electrode 102, an oxygen scavenger layer 108 on or over the switching stacked arrangement 106, a diffusion barrier layer 110 on or over the oxygen scavenger layer 108 and a second electrode 104 on or over the diffusion barrier layer 110.

For avoidance of doubt, FIG. 1 serves to illustrates some features of a non-volatile memory device according to various embodiments, and is not intended to limit for instance, the sizes, shapes, dimensions, aspect ratios, orientations etc. of the various features.

In various embodiments, the diffusion barrier layer 110 may serve as a diffusion barrier for ions (e.g., oxygen ions and metal ions from the neighboring second electrode 104), and may alternatively be referred to as an ion obstruction barrier layer. In various embodiments, the diffusion barrier layer 110 may have a thickness selected from a range from 1 nm to 10 nm. The diffusion barrier layer 110 may include any suitable material. In various embodiments, the diffusion barrier layer 110 may include a metal such as tantalum, titanium, hafnium or zirconium. In various embodiments, the diffusion barrier layer 110 may include a conductive oxide such as iridium oxide, ruthenium oxide or indium tin oxide. Generally speaking, metals such as tantalum or titanium may have an advantage over conductive oxides such as iridium oxide, ruthenium oxide or indium tin oxide, as the metals may be able to help scavenge oxygen. The diffusion barrier layer 110 may have an electrical conductivity selected from a range from 10⁴ ohm⁻¹m⁻¹ to 10⁷ ohm⁻¹m⁻¹. In various embodiments, the diffusion barrier layer 110 may include one or more materials selected from a group consisting of tantalum, titanium, hafnium, zirconium, iridium oxide, ruthenium oxide and indium tin oxide.

In various embodiments, the tunneling barrier layers may include a first material, while the active layers may include a second material different from the first material. An interatomic bonding energy of the first material may be greater than an interatomic bonding energy of the second material. The tunneling barrier layers may include a first metal oxide, while the active layers may include a second metal oxide different from the first metal oxide. For instance, the tunneling barrier layers may include a material selected from a group consisting of aluminum oxide, silicon oxide, magnesium oxide, calcium oxide, hafnium silicate and any combination thereof, while the active layers may include a material selected from a group consisting of tantalum oxide, hafnium oxide, zirconium oxide, titanium oxide, lanthanum oxide and any combination thereof. In various embodiments, the tunneling barrier layers may be more stable than the active layers.

In various embodiments, each of the tunneling barrier layers may have a thickness selected from a range from 0.5 nm to 1.5 nm.

In various embodiments, each of the active layers may have a thickness selected from a range from 1 nm to 3 nm.

In various embodiments, the first electrode 102 may include a metal or a conductive nitride. For instance, the first electrode 102 may include one or more materials selected from a group consisting of tungsten (W), aluminum (Al), copper (Cu), molybdenum (Mo), cobalt (Co), nickel (Ni), iron (Fe), platinum (Pt), palladium (Pd), gold (Au), iridium (Ir), ruthenium (Ru), rhodium (Rh), titanium tungsten (TiW), tantalum tungsten (TaW), titanium nitride (TiN) and tantalum nitride (TaN).

In various embodiments, the second electrode 104 may include a metal or a conductive nitride. For instance, the second electrode 104 may include one or more materials selected from a group consisting of platinum (Pt), palladium (Pd), gold (Au), iridium (Ir), ruthenium (Ru), rhodium (Rh), titanium nitride (TiN) and tantalum nitride (TaN).

In various embodiments, an oxygen concentration layer of the oxygen scavenger layer 108 (alternatively referred to as scavenger layer) may be lower than an oxygen concentration layer of the last active layer. The scavenger layer 108 may include a metal oxide. For instance, the oxygen scavenger layer may include TaO_{z}, wherein 0<z<1.

In various embodiments, the non-volatile memory device may further include a further oxygen scavenger layer between the oxygen scavenger layer 108 and the diffusion layer 110. An oxygen concentration layer of the further oxygen scavenger layer may be lower than the oxygen scavenger layer 108.

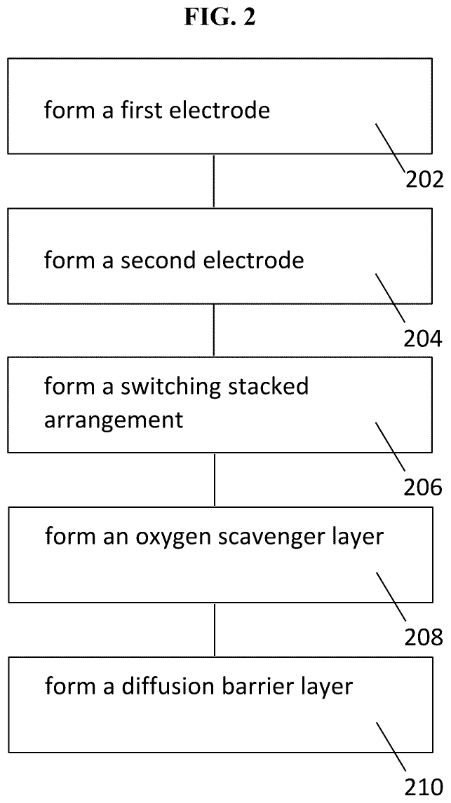

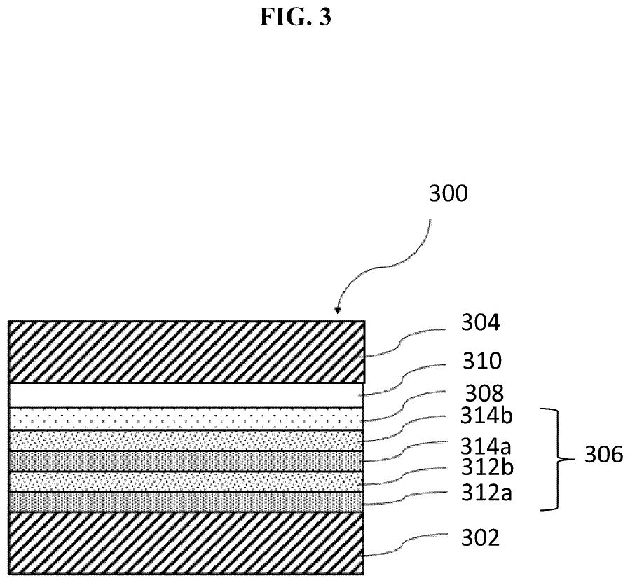

FIG. 2 is a general illustration of a method of forming a non-volatile memory device according to various embodiments. The method may include, in 202, forming a first electrode. The method may also include, in 204, forming a second electrode. The method may further include, in 206, forming a switching stacked arrangement between the first electrode and the second electrode. The method may additionally include, in 208, forming an oxygen scavenger layer between the switching stacked arrangement and the second electrode. The method may also include, in 210, forming a diffusion barrier layer between the oxygen scavenger layer and the second electrode. The switching stacked arrangement may include alternating tunneling barrier layers and active layers. A first tunneling barrier layer of the tunneling barrier layers may be in physical contact with the first electrode. A last active layer of the active layers may be in physical contact with the oxygen scavenger layer. A bandgap of the tunneling barrier layers may be greater than a bandgap of the active layers.

In other words, the method may include forming a non-volatile memory device by forming the first electrode, the second electrode, the switching stacked arrangement, the oxygen scavenger layer and the diffusion barrier layer.

For avoidance of doubt, FIG. 2 is not intended to limit the sequence of the various steps. In various embodiments, the switching stacked arrangement may be formed after forming the first electrode. The oxygen scavenger layer may be formed after forming the switching stacked arrangement. The diffusion barrier layer may be formed after forming the oxygen scavenger layer. The second electrode may be formed after forming the diffusion barrier layer. In various other embodiments, the second electrode may be formed first. The diffusion barrier layer may be formed after forming the second electrode. The oxygen scavenger layer may be formed after forming the diffusion barrier layer. The switching stacked arrangement may be formed after forming the oxygen scavenger layer. The first electrode may be formed after forming the switching stacked arrangement.

In various embodiments, the tunneling barrier layers, the active layers, the oxygen scavenger layer and the diffusion barrier layer may be formed via sputtering, chemical vapor deposition (CVD), atomic layer deposition (ALD), electron-beam deposition, thermal evaporation, or molecular beam epitaxy. Atomic layer deposition (ALD) may be able to deposit large-scale, highly uniform and very thin films.

In various embodiments, the diffusion barrier layer may have a thickness selected from a range from 1 nm to 10 nm. The diffusion barrier layer may include any suitable material. The diffusion barrier layer may have an electrical conductivity selected from a range from 10⁴ ohm⁻¹m⁻¹to 10⁷ ohm⁻¹m⁻¹. In various embodiments, the diffusion barrier layer may include one or more materials selected from a group consisting of tantalum, titanium, hafnium, zirconium, iridium oxide, ruthenium oxide and indium tin oxide.

In various embodiments, the tunneling barrier layers may include a first material, while the active layers may include a second material different from the first material. An interatomic bonding energy of the first material may be greater than an interatomic bonding energy of the second material. The tunneling barrier layers may include a first metal oxide, while the active layers may include a second metal oxide different from the first metal oxide. For instance, the tunneling barrier layers may include a material selected from a group consisting of aluminum oxide, silicon oxide, magnesium oxide, calcium oxide, hafnium silicate and any combination thereof, while the active layers may include a material selected from a group consisting of tantalum oxide, hafnium oxide, zirconium oxide, titanium oxide, lanthanum oxide and any combination thereof. In various embodiments, the tunneling barrier layers may be more stable than the active layers.

In various embodiments, each of the tunneling barrier layers may have a thickness selected from a range from 0.5 nm to 1.5 nm.

In various embodiments, each of the active layers may have a thickness selected from a range from 1 nm to 3 nm.

In various embodiments, the first electrode may include a metal or a conductive nitride. For instance, the first electrode may include one or more materials selected from a group consisting of tungsten (W), aluminum (Al), copper (Cu), molybdenum (Mo), cobalt (Co), nickel (Ni), iron (Fe), platinum (Pt), palladium (Pd), gold (Au), iridium (Ir), ruthenium (Ru), rhodium (Rh), titanium tungsten (TiW), tantalum tungsten (TaW), titanium nitride (TiN) and tantalum nitride (TaN).

In various embodiments, the second electrode may include a metal or a conductive nitride. For instance, the second electrode may include one or more materials selected from a group consisting of platinum (Pt), palladium (Pd), gold (Au), iridium (Ir), ruthenium (Ru), rhodium (Rh), titanium nitride (TiN) and tantalum nitride (TaN).

In various embodiments, an oxygen concentration layer of the oxygen scavenger layer may be lower than an oxygen concentration layer of the last active layer. The oxygen scavenger layer may include a metal oxide. For instance, the scavenger layer may include TaO_{z}, wherein 0<z<1.

In various embodiments, the method may further include forming a further oxygen scavenger layer between the oxygen scavenger layer and the diffusion layer. An oxygen concentration of the further oxygen scavenger layer may be lower than an oxygen concentration of the oxygen scavenger layer.

FIG. 3 shows a cross-sectional schematic of a non-volatile memory device 300 according to various embodiments. As shown in FIG. 3, the device 300 may include two electrodes: a first electrode 302 and a second electrode 304. The device 300 may include between the electrodes 302, 304 the following: a switching stacked arrangement 306, an oxygen scavenger layer 308 and a diffusion barrier layer 310. The switching stacked arrangement 306 includes multiple layers: a first tunneling barrier layer 312a, a first active layer 312b, a second tunneling barrier layer 314a, and a second active layer 314b.

Referring to FIG. 3, the first tunneling barrier layer 312a may be a material layer having a much larger band gap than the first active layer 312b. In a more specific example, when a tantalum (Ta) oxide is used for the first active layer 312b, the material used for the first tunneling barrier layer 312a may be one of aluminum oxide (AlOₓ), silicon oxide (SiOₓ), magnesium oxide (MgO), calcium oxide (CaO) and hafnium silicate (HfSiOₓ), any combination thereof, or the like, wherein the “x” may refer to any suitable positive number, e.g., 1<x≤1.5 for AlOₓ. Generally speaking, the “x” value may be such that it meets the requirement that the band gap of the first tunneling barrier layer 312a is larger than that of the first active layer 312b. The second tunneling barrier layer 314a may have the same or similar material properties to that of the first tunneling barrier 312a. The second active layer 314b may have the same or similar material properties to that of the first active layer 312b. In other words, the second tunneling barrier layer 314a may be a repeated unit of the first tunneling barrier 312a, and the second active layer 314b may be a repeated unit of the first active layer 312b. For example, with a Al₂O₃₋ₓ/Ta₂O_{5-y}/Al₂O₃₋ₓ/Ta₂O_{5-y} configuration (wherein e.g., 0≤x≤0.5, 4.5≤y≤5), it can also be written as [Al₂O₃₋ₓ/Ta₂O_{5-y}]₂. In this example, the first tunneling barrier layer 312a and the second tunneling barrier layer 314a may both include Al₂O₃₋ₓ, and the first active layer 312b and the second active layer 314b may both include Ta₂O_{5-y}. The repeating number is 2 in this example of the switching stacked arrangement 306 (n=2).

For avoidance of doubt, while FIG. 3 shows the first electrode 302 as the bottom electrode, with the switching stacked arrangement 306 on the first electrode 302, the oxygen scavenger layer 308 on the switching stacked arrangement 306, the diffusion barrier layer 310 on the oxygen scavenger layer 308 and the second electrode 304 as the top electrode on the diffusion barrier layer 310, it may be understood that if the device 300 is turned over, elements and principles described still apply. In this case, the first electrode 302 may be the top electrode while the second electrode 304 may be the bottom electrode. The non-volatile memory device 300 may be oriented in any direction.

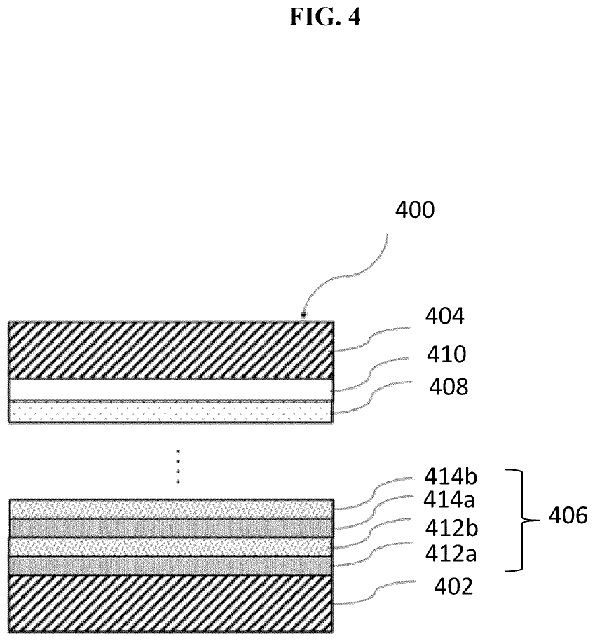

FIG. 4 shows a cross-sectional schematic of another non-volatile memory device 400 according to various embodiments. The device 400 may also include a first electrode 402 and a second electrode 404. The device 400 may include between the electrodes 402, 404 the following: a switching stacked arrangement 406, an oxygen scavenger layer 408 and a diffusion barrier layer 410. Compared to the device 300 shown in FIG. 3, the switching stacked arrangement 406 of the device 400 may have more repeated layers (n>2). For example, [Al₂O₃₋ₓ/Ta₂O_{5-y}]ₙ refers to the repeating of the tunneling barrier layer Al₂O₃₋ₓ and the active layer Ta₂O_{5-y} for n times (n>2). For instance, the switching stacked arrangement 406 may include first tunneling barrier layer 412a, first active layer 412b on the first tunneling barrier layer 412a, second tunneling barrier layer 414a on the first active layer 412b, second active layer 414b on the second tunneling barrier layer 414a and so on.

The tunneling barrier layer 412a (and 414a, and so on) may have a stoichiometric composition or a composition close to a stoichiometric composition. For example, the tunneling barrier layer 412a (and 414a, and so on) may be formed of aluminum (Al) oxide such as Al₂O₃ layer or may have a composition substantially close to Al₂O₃ (e.g., Al₂O₃₋ₓ, where 0<x≤0.5), and may thus be more stable than the first active layer 412b. The tunneling barrier layer 412a (and 414a, and so on) material may have an interatomic bonding energy greater than that of the first active layer 412b. The tunneling barrier layer 412a (and 414a, and so on) may function to improve reliability and stability of the resistance change characteristic of the memory device 400.

Referring to FIGS. 3-4, the oxygen scavenger layer 308, 408 may be disposed next to the switching stacked arrangement 306, 406. The purpose of the scavenger layer 308, 408 may be to scavenge oxygen ions from the active layers nearby, or as an oxygen vacancy reservoir. For example, with the active layer 312b, 412b (and 314b, 414b and so on) as Ta₂O_{5-y} (e.g.,. 4.5≤y≤5), the oxygen scavenger layer 308, 408 may be TaO_{z} (wherein 0<z<1) whose oxygen concentration is much smaller than that of the active layer.

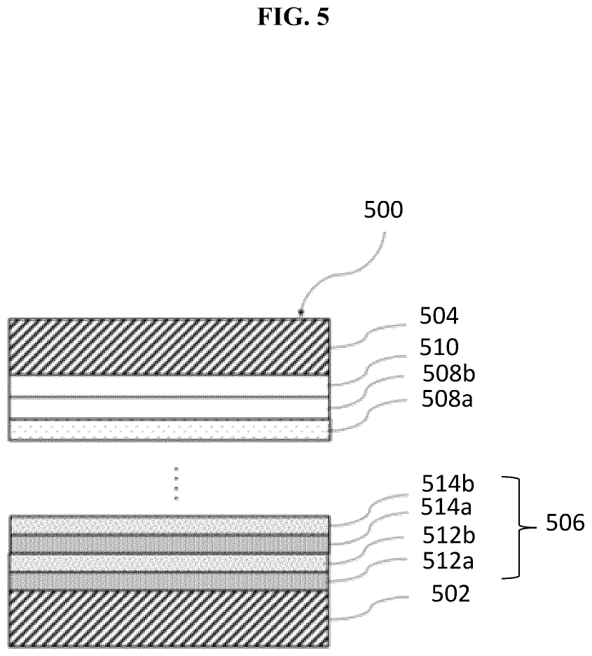

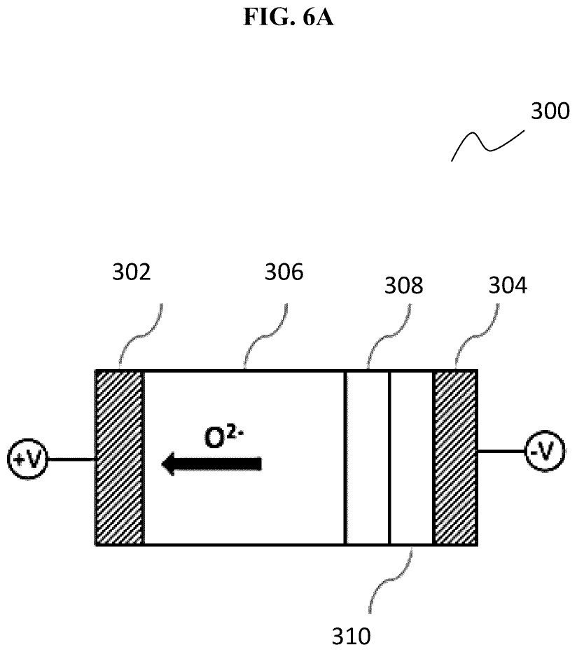

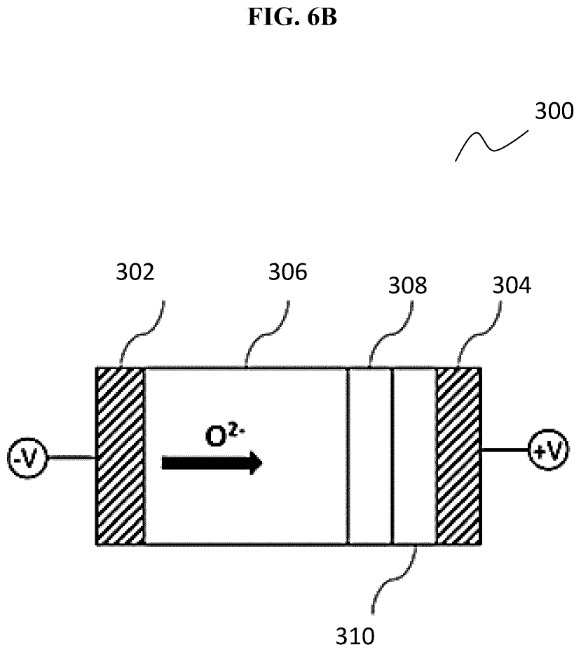

FIG. 5 shows a cross-sectional schematic of another non-volatile memory device 500 according to various embodiments. The device 500 may include between the electrodes 502, 504 the following: a switching stacked arrangement 506 (including tunneling barrier layers 512a, 514a and so on, as well as active layer 512b, 514b and so on), an oxygen scavenger layer 508a and a diffusion barrier layer 510. The device 500 may further include a further oxygen scavenger layer 508b between the oxygen scavenger layer 508a and the diffusion layer 510.

In a more specific example, with the active layer 512b (and 514b, and so on) as Ta₂O_{5-y}, the first scavenger layer could be TaO_{z}, and the second scavenger layer could be TaO_{w}. The oxygen concentration decreases from Ta₂O_{5-y} to TaO_{z}, and further decreasing to TaO_{w} whose oxygen concentration is the lowest. For instance, z may be 0.9 and w may be 0.5.

With reference to FIGS. 3-5, the diffusion barrier layer 310, 410, 510 may be disposed between the oxygen scavenger layer(s) 308, 408, 508a-b and the second electrode 304, 404, 504. The purpose of the diffusion barrier layer 310, 410, 510 may be to prevent or reduce the diffusion of metal atoms diffused from the nearby electrode 304, 404, 504 into the oxygen scavenger layer(s) 308, 408, 508a-b and the switching stacked arrangement 306, 406, 506. For example, with a TaO_{z}/Ta/Pt structure, where Pt is the second electrode (i.e., the second electrode is made of platinum or Pt), and Ta is the diffusion barrier layer between Pt and TaO_{z} (i.e., the diffusion barrier layer is made of tantalum or Ta), the insertion of a Ta layer may significantly decrease the diffusion of oxygen ions and Pt from the Pt electrode into the neighboring oxide. Another example is to use a conductive oxide as the diffusion barrier layer. For example, with a TaO_{z}/IrO₂/Pt structure, the migration of oxygen ions and Pt atoms to the TaO_{y} layer may be inhibited because of the addition of the IrO₂ layer. With the IrO₂ layer working as an oxygen diffusion barrier, the exchange of oxygen ions between Pt and TaO_{z} may be obstructed. The material used for the diffusion barrier layer may be one of tantalum (Ta), titanium (Ti), hafnium (Hf), zirconium (Zr), iridium oxide (IrOₓ), ruthenium oxide (RuOₓ) and indium tin oxide (ITO), a combination thereof, or the like, wherein the “x” may refer to any positive number, e.g., 1<x≤2 for IrOₓ and RuOₓ, respectively. In other words, “x” may be such that 1<x≤2 for IrOₓ or RuOₓ.

FIG. 6A shows a cross-sectional schematic illustrating an operational mechanism based on the non-volatile memory device 300 shown in FIG. 3 according to various embodiments. FIG. 6B shows another cross-sectional schematic illustrating the operational mechanism based on the non-volatile memory device 300 shown in FIG. 3 according to various embodiments. As shown in FIGS. 6A-B, an exchange of oxygen ions may take place when a potential difference or voltage is applied between the electrodes 302 and 304. When different polarities of the potential difference or voltage are applied, oxygen ions may move between the tunneling barrier layers and the active layers in the switching stacked arrangement 306. The formation of conductive filaments within the active layers may lead to a low resistance state (LRS, an ON-state), and the fracture of conductive filaments within the active layers may lead to a high resistance state (HRS, an OFF-state).

The first electrode 302 may be formed of a metal or a conductive nitride. For instance, the first electrode 302 may include tungsten (W), aluminum (Al), copper (Cu), molybdenum (Mo), cobalt (Co), nickel (Ni), iron (Fe), platinum (Pt), palladium (Pd), gold (Au), iridium (Ir), ruthenium (Ru), rhodium (Rh), titanium tungsten (TiW), tantalum tungsten (TaW), titanium nitride (TiN), tantalum nitride (TaN) and/or any other suitable materials.

The second electrode 304 may be formed of a chemically noble metal or a conductive nitride which is oxidation resistant. The second electrode 304 may include platinum (Pt), palladium (Pd), gold (Au), iridium (Ir), ruthenium (Ru), rhodium (Rh), titanium nitride (TiN), tantalum nitride (TaN) and/or any other suitable materials.

FIG. 7 shows a plot of current (in Amperes or A) as a function of voltage (in volts or V) illustrating the voltage-current characteristics of the electroforming process of a non-volatile memory device according to various embodiments. The memory device is a W/[Al₂O₃₋ₓ/Ta₂O_{5-y}]₂/TaO_{z}/Ta/Pt structure with an arrangement as shown in FIG. 3. The first electrode may include tungsten (W) while the second electrode may include platinum (Pt), with the switching stacked arrangement being [Al₂O₃₋ₓ/Ta₂O_{5-y}]₂, the oxygen scavenger layer including TaO_{z} and the diffusion barrier layer including Ta. In this example, the Pt may be the top electrode and the W may be the bottom electrode. The electroforming process may be performed by applying a negative voltage to the top electrode Pt, and the bottom electrode W may be electrically grounded. During the forming process, the current increases with the voltage applied. When the applied voltage is greater than the forming voltage, the current increases to the limit or the compliance current value. In this example voltage-current curve, the forming voltage is around −1.8 V, and the compliance current is 1E-4 A. Through the electroforming process, the electrical resistance of the memory device may be switched from an initial high resistance state to a low resistance state, and conductive filaments or bridges may be formed across the layers between the electrodes. The conductive filaments may extend through the switching stacked arrangement including alternating tunneling barrier layers and active layers, as well as through the oxygen scavenger layer.

FIG. 8 shows a plot of current (in Amperes or A) as a function of voltage (in volts or V) of the non-volatile memory device according to various embodiments after the electroforming process described in FIG. 7. The voltage-current curves show a bipolar resistive switching characteristic. The non-volatile memory device may change from an OFF-state to an ON-state with a negative set voltage applied, and from an ON-state to an OFF-state with a positive reset voltage applied. Both set and reset voltages may typically be well below −1.0 V and +1.0 V, respectively. The experimental results may prove the capability of the memory device for low power applications.

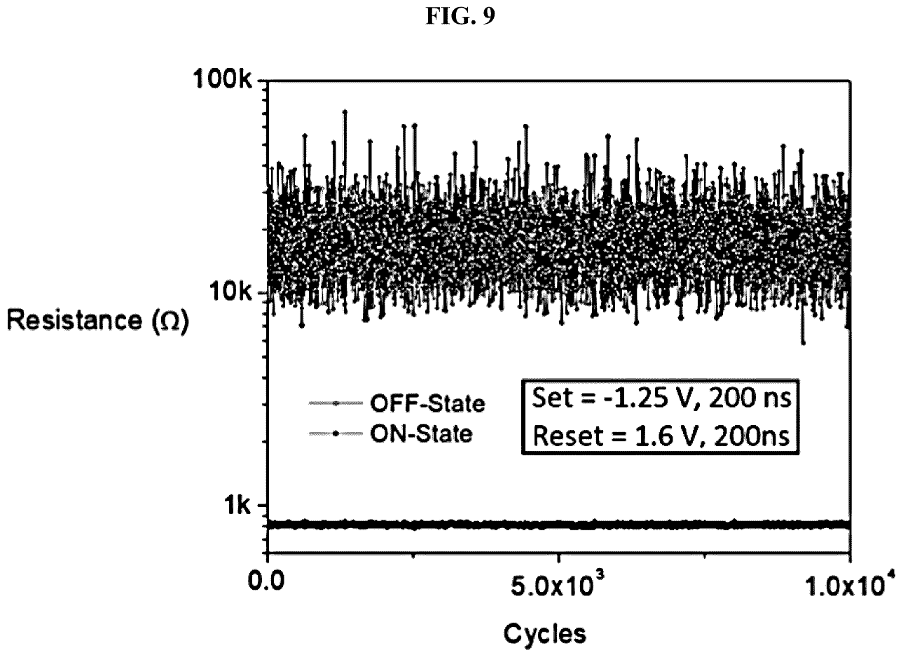

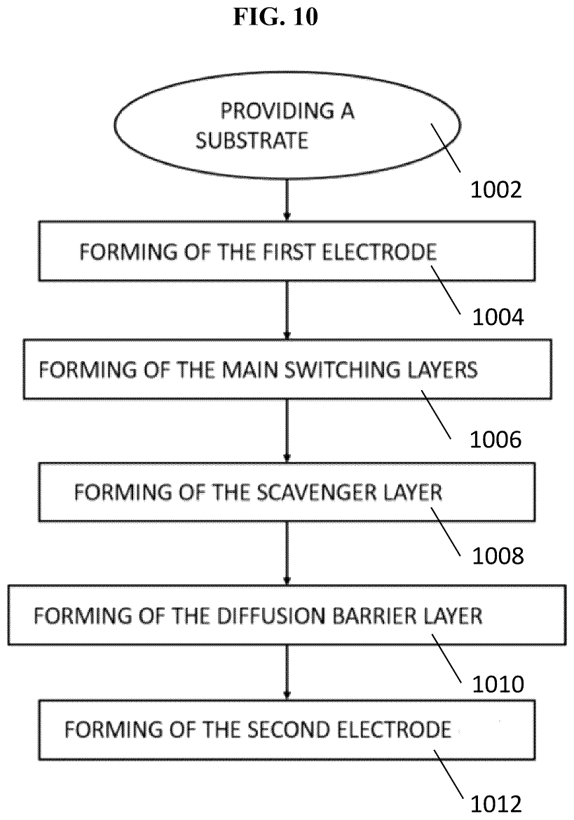

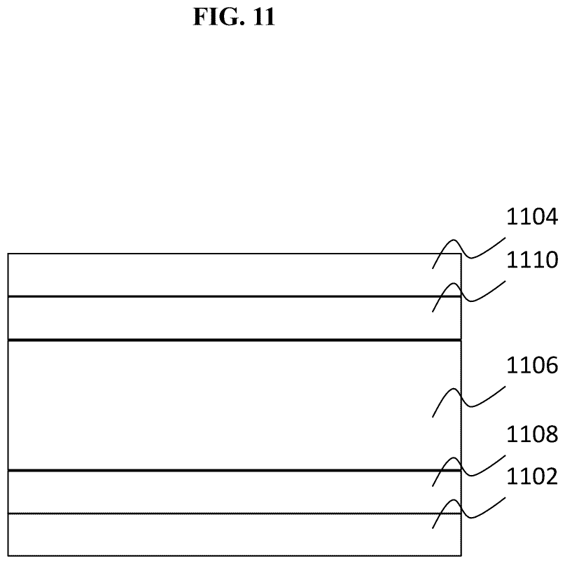

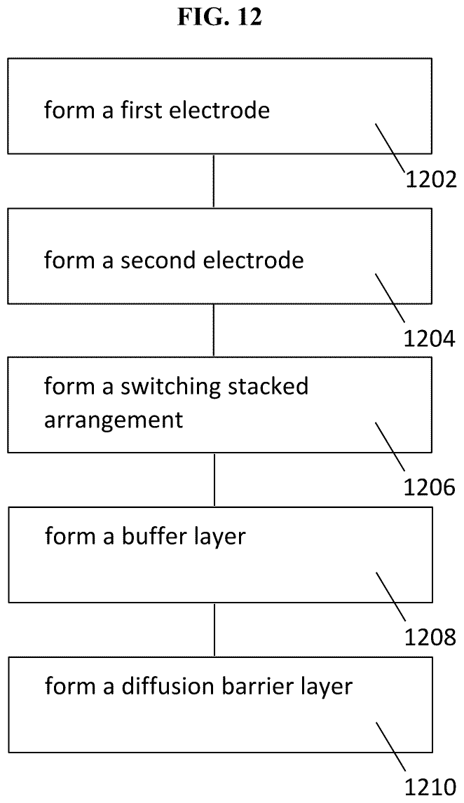

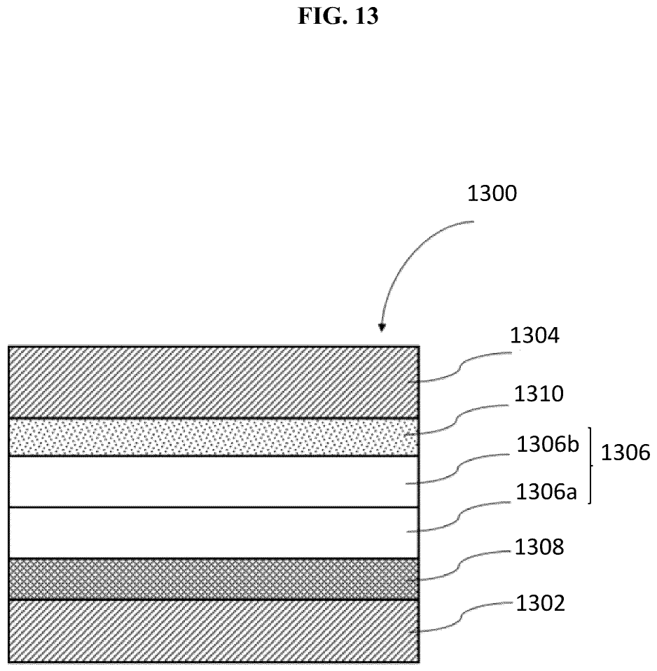

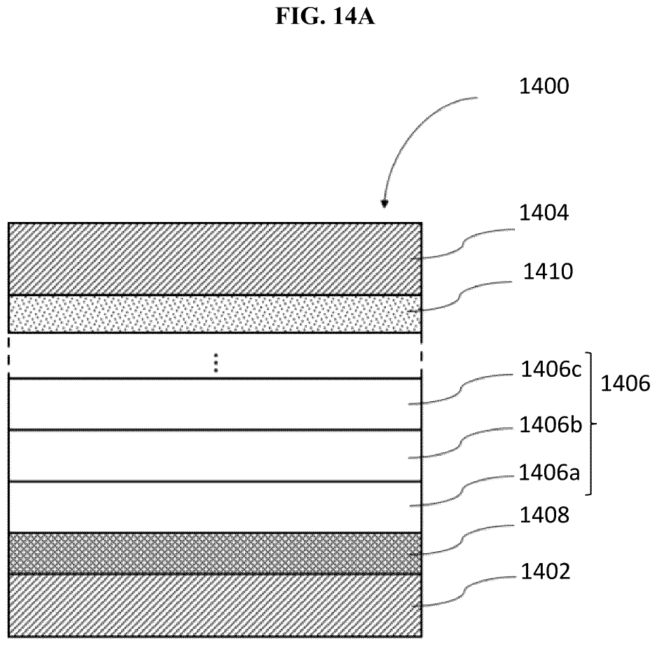

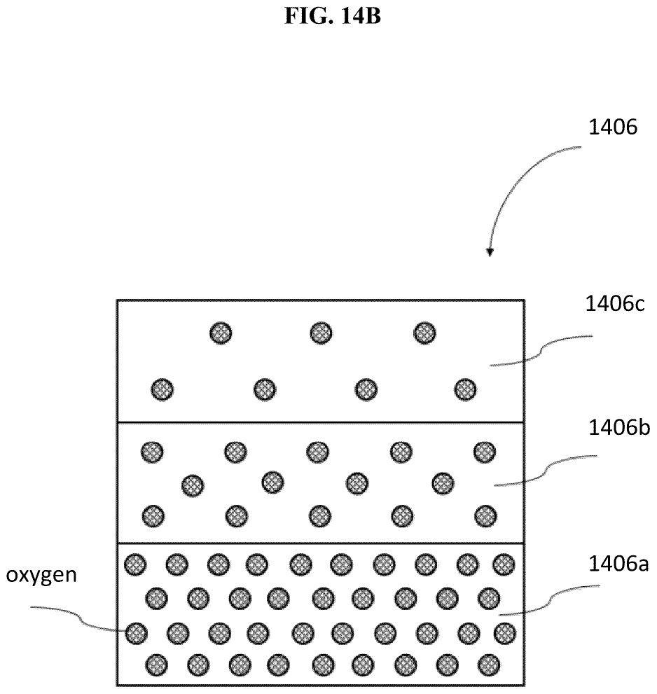

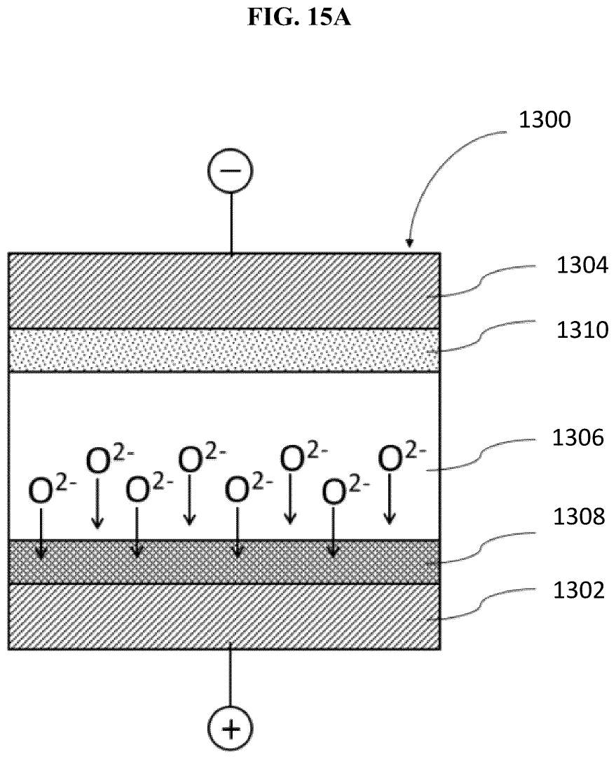

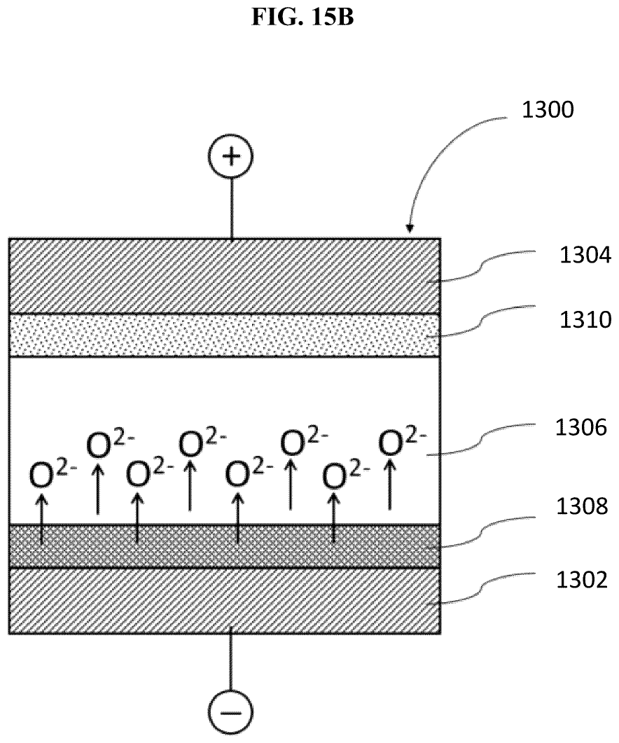

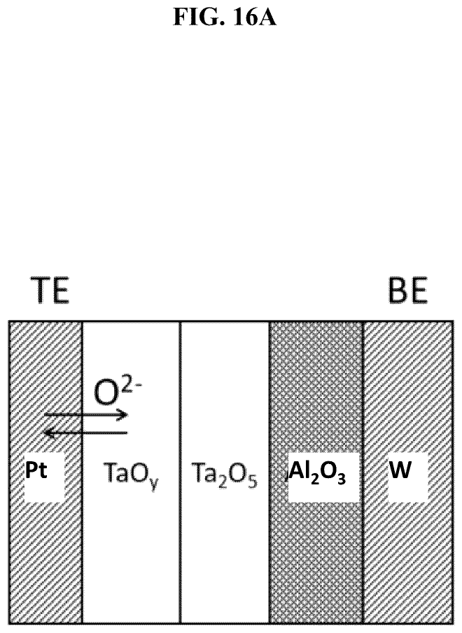

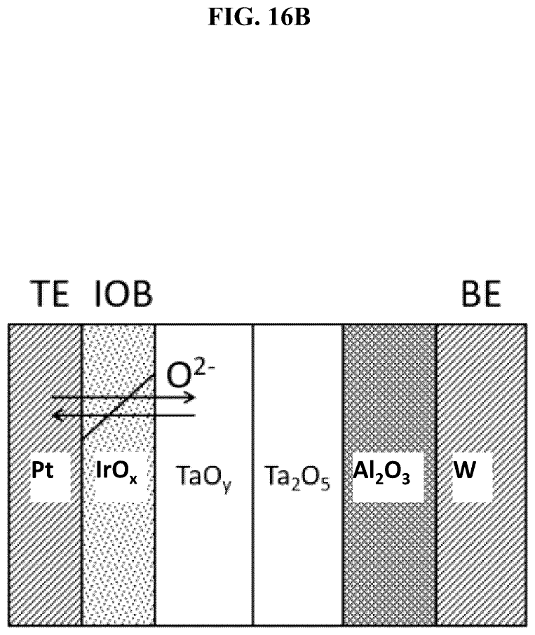

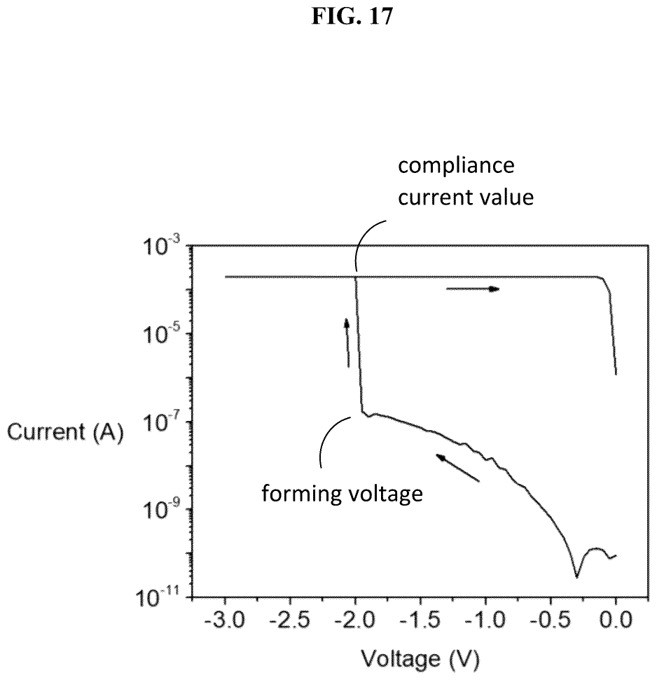

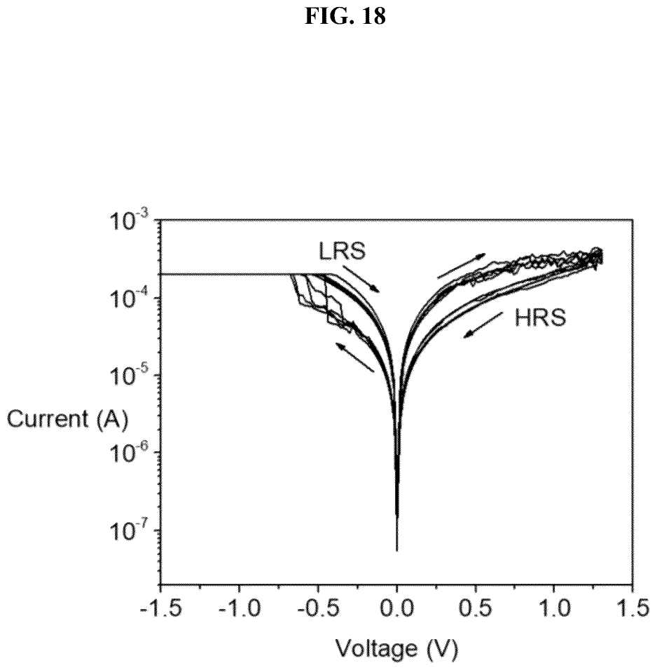

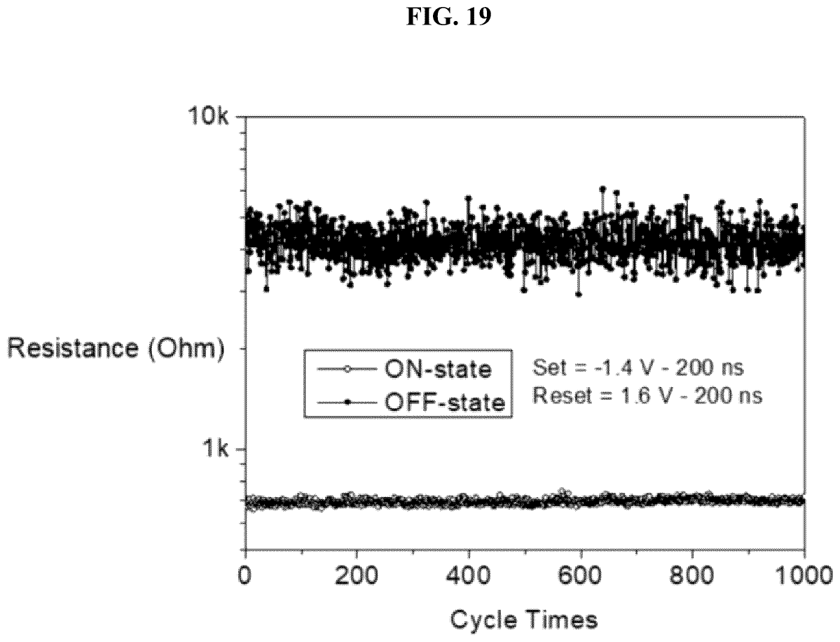

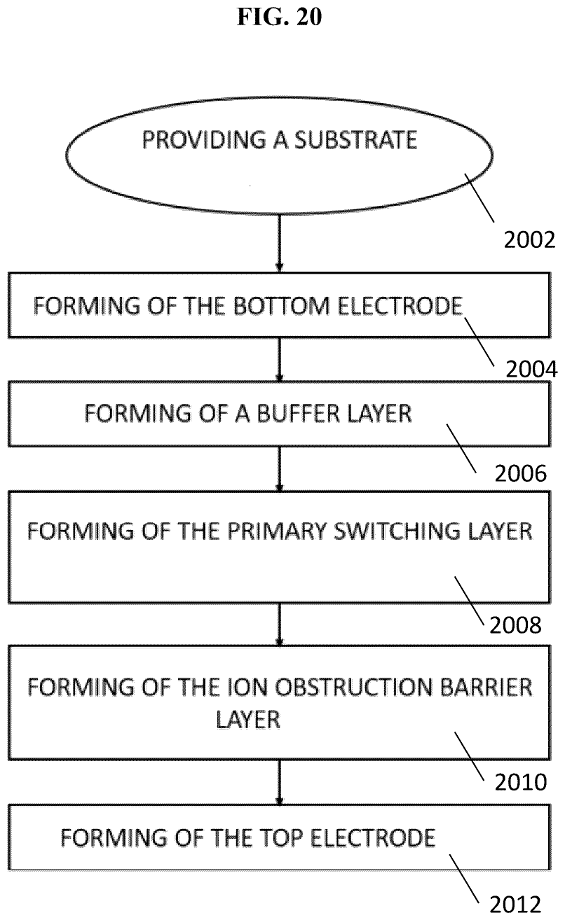

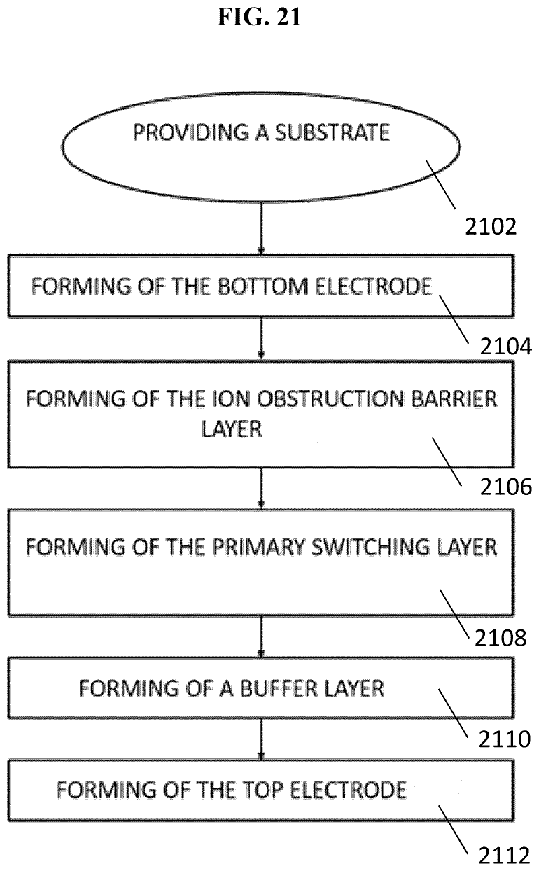

FIG. 9 shows a plot of resistance (in ohms or Ω) as a function of cycles illustrating a voltage pulse endurance test results of the non-volatile memory device used for the plots shown in FIGS. 7-8 according to various embodiments. The voltage pulse endurance test may be used to determine endurance of a non-volatile memory under high-speed switching operations. The test may include a set voltage pulse to switch the device from an OFF-state to an ON-state, wherein the set voltage pulse has a height of −1.25 V and a pulse width of 200 ns. Sequentially, a reset voltage pulse is applied to switch the device from an ON-state to an OFF-state, wherein the reset voltage pulse has a height of 1.6 V and a pulse width of 200 ns. The voltage pulse endurance test results in FIG. 9 show that the device can be continuously operated for over 1E4 times, and a stable resistance characteristic can be maintained.

FIG. 10 shows a flow chart of forming a non-volatile memory device according to various embodiments. The method may start from providing a substrate (Step 1002). A bottom electrode may then be formed (Step 1004), followed by the formation of the switching stacked arrangement, i.e. main switching layers (Step 1006). The switching stacked arrangement may be formed by repeated alternate deposition to form the tunneling barrier layers and the active layers. Step 1008 describes the formation of the oxygen scavenger layer and step 1010 describes the formation of the diffusion barrier layer. The last may be the formation of the top electrode (Step 1012). The film thickness may be in the range from 1 to 100 nanometers (nm) for each of the electrodes, from 0.5 to 1.5 nm for each of the tunneling barrier layers, and from 1 to 3 nm for each of the active layers. An electroforming process may be needed to form conductive filaments or bridges within the layers between the electrodes. Decreasing the thicknesses of the layers between the electrodes may result in a decrease of the electroforming voltage. Appropriate growth conditions, such as gas flow ratio, chamber pressure, chemical composition and substrate temperature, may be chosen to achieve the structure desired for a specific layer. For example, when sputtering from a Ta target is used, the O/Ta ratio may be controlled through change of the O₂/Ar flow ratio during the reactive sputtering process, for the deposition of a TaOₓ film.

Various embodiments may relate to a non-volatile memory device including a first electrode, a second electrode, and a switching stacked arrangement disposed between the first electrode and the second electrode. The switching stacked arrangement may include repeated units of two regions, a first region of metal oxide as a tunneling barrier layer, a second region of metal oxide as an active layer; the first tunneling barrier layer may be physically connected to the first electrode and the first active layer; the last active layer may be physically connected to the last tunneling barrier layer and the scavenger layer; the scavenger layer may be physically connected to the last active layer and the diffusion barrier layer; the diffusion barrier layer may be physically connected to the scavenger layer and the second electrode; wherein the last active layer having a high oxygen concentration and physically connected to the scavenger layer, the scavenger layer having a low oxygen concentration and physically connected to the diffusion barrier layer.

In various embodiments, the first electrode may be formed of one or a metal and a conductive nitride. The first electrode may include at least one of W, Al, Cu, Mo, Co, Ni, Fe, Pt, Pd, Au, Ir, Ru, Rh, TaW, TiW, TiN and TaN.

The tunneling barrier layer(s) may be formed of a first metal oxide. The first metal oxide may include at least one of AlOₓ, SiOₓ, MgO, CaO, HfSiOₓ, and a combination thereof.

The active layer(s) may be formed of a second metal oxide. The second metal oxide may include one of Ta oxide, Hf oxide, Zr oxide, Ti oxide, La oxide, and a combination thereof.

The first metal oxide may have a band gap greater than the second metal oxide. The second metal oxide may include Ta₂O_{5-y}, wherein 4.5≤y≤5.

The oxygen scavenger layer may be formed of a third metal oxide. The third metal oxide may be formed of an oxide from the same group as the second metal oxide or a different group from the second metal oxide.

The oxygen concentration of the scavenger layer may be lower than the oxygen concentration of the active layer. The third metal oxide includes TaO_{z}, wherein 0<z<1. The third metal oxide may be formed of an oxide from the same group as the second metal oxide, but may be doped with a metal element different from the second metal oxide.

The diffusion barrier layer may be formed of a metal or a conductive oxide. The diffusion barrier layer may include Ta, Ti, IrOₓ, RuOₓ and ITO, a combination thereof, or the like.

Each tunneling barrier layer may have a thickness in a range from 0.5 nm to 1.5 nm. Each of the active layers may have a thickness in a range from 1 nm to 3 nm.

FIG. 11 is a general illustration of a non-volatile memory device according to various embodiments. The non-volatile memory device may include a first electrode 1102. The non-volatile memory device may also include a second electrode 1104. The non-volatile memory device may additionally include a switching stacked arrangement 1106 between the first electrode 1102 and the second electrode 1104. The non-volatile memory device may also include a buffer layer 1108 between the first electrode layer 1102 and the switching stacked arrangement 1106. The non-volatile memory device may further include a diffusion barrier layer 1110 between the switching stacked arrangement 1106 and the second electrode 1104, the diffusion barrier layer 1110 configured to at least reduce a diffusion of oxygen ions between the switching stacked arrangement 1106 and the second electrode 1104. An oxygen concentration of the switching stacked arrangement 1106 may decrease from a first switching layer or region of the switching stacked arrangement 1106 closest to the first electrode 1102 to a last switching layer or region of the switching stacked arrangement 1106 closest to the second electrode 1104. The diffusion barrier layer 1110 may include a material selected from a group consisting of iridium oxide, ruthenium oxide and indium tin oxide.

In other words, the non-volatile memory device may include a first electrode 1102, a buffer layer 1108 on or over the first electrode 1102, a switching stacked arrangement 1106 on or over the buffer layer 1108, a diffusion barrier layer 1110 on or over the switching stacked arrangement 1106, and a second electrode 1104 on or over the diffusion barrier layer 1110.

For avoidance of doubt, FIG. 11 serves to illustrates some features of a non-volatile memory device according to various embodiments, and is not intended to limit for instance, the sizes, shapes, dimensions, aspect ratios, orientations etc. of the various features.

In various embodiments, the diffusion barrier layer 1110 may have a thickness selected from a range from 1 nm to 10 nm. The diffusion barrier layer 110 may have an electrical conductivity selected from a range from 10⁴ ohm⁻¹m⁻¹ to 10⁷ ohm⁻¹m⁻¹.

In various embodiments, the first electrode 1102 may include a metal or a conductive nitride. The first electrode 1102 may include one or more materials selected from a group consisting of tungsten (W), aluminum (Al), copper (Cu), molybdenum (Mo), cobalt (Co), nickel (Ni), iron (Fe), platinum (Pt), palladium (Pd), gold (Au), iridium (Ir), ruthenium (Ru), rhodium (Rh), titanium tungsten (TiW), tantalum tungsten (TaW), titanium nitride (TiN) and tantalum nitride (TaN).

In various embodiments, the second electrode 1104 may include a metal or a conductive nitride. The first electrode 1104 may include one or more materials selected from a group consisting of platinum (Pt), palladium (Pd), gold (Au), iridium (Ir), ruthenium (Ru), rhodium (Rh), titanium nitride (TiN) and tantalum nitride (TaN).

In various embodiments, the buffer layer 1108 may include a metal oxide. The buffer layer 1108 may include a material selected from a group consisting of aluminum oxide, silicon oxide, magnesium oxide, calcium oxide, hafnium silicate and any combination thereof.

In various embodiments, a bandgap of the buffer layer 1108 may be greater than a bandgap of the first switching layer or region of the switching stacked arrangement 1106. The buffer layer 1108 may have a thickness selected from a range from 0.5 nm to 5 nm.

In various embodiments, the switching stacked arrangement 1106 may have a stepped oxygen concentration profile such that the oxygen concentration of the switching stacked arrangement 1106 decreases from the first switching layer or region to the last switching layer or region in steps. In various other embodiments, the switching stacked arrangement 1106 may have a sloping oxygen concentration profile such that the oxygen concentration of the switching stacked arrangement 1106 decreases from the first switching layer or region to the last switching layer or region in a sloping manner.

FIG. 12 is a general illustration of a method of forming a non-volatile memory device according to various embodiments. The method may include, in 1202, forming a first electrode. The method may also include, in 1204, forming a second electrode. The method may further include, in 1206, forming a switching stacked arrangement between the first electrode and the second electrode. The method may additionally include, in 1208, forming a buffer layer between the first electrode layer and the switching stacked arrangement. The method may further include, in 1210, forming a diffusion barrier layer between the switching stacked arrangement and the second electrode, the diffusion barrier layer configured to at least reduce a diffusion of oxygen ions between the switching stacked arrangement and the second electrode. An oxygen concentration of the switching stacked arrangement may decrease from a first switching layer or region of the switching stacked arrangement closest to the first electrode to a last switching layer or region of the switching stacked arrangement closest to the second electrode. The diffusion barrier layer may include a material selected from a group consisting of iridium oxide, ruthenium oxide and indium tin oxide.

In other words, the method may include forming a non-volatile memory device by forming the first electrode, the second electrode, the switching stacked arrangement, the buffer layer and the diffusion barrier layer.

For avoidance of doubt, FIG. 12 is not intended to limit the sequence of the various steps. In various embodiments, the buffer layer may be formed after forming the first electrode. The switching stacked arrangement may be formed after forming the buffer layer. The diffusion barrier layer may be formed after forming the switching stacked arrangement. The second electrode may be formed after forming the diffusion barrier layer. In various other embodiments, the diffusion barrier layer may be formed after forming the second electrode. The switching stacked arrangement may be formed after forming the diffusion barrier layer. The buffer layer may be formed after forming the switching stacked arrangement. The first electrode may be formed after forming the buffer layer.

In various embodiments, the first electrode, the second electrode, the switching stacked arrangement, the buffer layer, and the diffusion barrier layer may be formed via one or more selected from physical-based deposition processes, chemical-based deposition processes, or a combination thereof.

In various embodiments, the first electrode, the second electrode, the switching stacked arrangement, the buffer layer, and the diffusion barrier layer may be formed via one or more processes selected from a group consisting of sputtering, electron beam evaporation and chemical vapor deposition (e.g. atomic layer deposition or ALD).

FIG. 13 shows a cross-sectional schematic of a non-volatile memory device 1300 according to various embodiments. As shown in FIG. 13, the non-volatile memory device 1300 may include the electrodes 1302 and 1304, and a resistive switching region disposed therebetween. The resistive switching region may include a buffer layer 1308, a switching stacked arrangement 1306 including a first active layer 1306a and a second active layer 1306b, and a diffusion barrier layer 1310 (alternatively referred to as an ion obstruction barrier layer. The switching stacked arrangement 1306 may have a double layer structure (n=2), i.e. including the first active layer 1306a and the second active layer 1306b.

For avoidance of doubt, while FIG. 13 shows the first electrode 1302 as the bottom electrode, with the buffer layer 1308 on the first electrode 1302, the switching stacked arrangement 1306 on the buffer layer, the diffusion barrier layer 1310 on the switching stacked arrangement 1306, and the second electrode 1304 as the top electrode on the diffusion barrier layer 1310, it may be understood that is the device 1300 is turned over, elements and principles described still apply. In this case, the first electrode 1302 may be the top electrode while the second electrode 1304 may be the bottom electrode. The non-volatile memory device 1300 may be oriented in any direction.

FIG. 14A shows a cross-sectional schematic of another non-volatile memory device 1400 according to various embodiments. As shown in FIG. 14A, the non-volatile memory device 1400 may include the electrodes 1402 and 1404, and a resistive switching region disposed therebetween. The resistive switching region may include a buffer layer 1408, a switching stacked arrangement 1406 with a multiple layered structure (n>2) including a first active layer 1406a, a second active layer 1406b, a third active layer 1406c and so on, as well as a diffusion barrier layer 1410.

For device 1300, the switching stacked arrangement 1306 may have a double layer structure with the first active layer 1306a in contact or connected to the buffer layer 1308 and the second active layer 1306b in contact or connected to the diffusion barrier layer 1310. The first active layer 1306a may be configured to have a higher oxygen concentration than that of the second active layer 1306b. For example, the switching stacked arrangement 1306 may be Ta₂O₅/TaO₂, where the first active layer 1306a includes Ta₂O₅, and the second active layer 1306b includes TaO₂.

For device 1400, the switching stacked arrangement 1406 may be a multiple layered structure (n>2) including a first active layer 1406a, a second active layer 1406b, a third active layer 1406c and so on. There may be an oxygen gradient across different layers of the switching stacked arrangement 1406. FIG. 14B shows the switching stacked arrangement 1406 with a triple-layered structure including three active layers 1406a-c according to various embodiments. The first active layer 1406a may have a high oxygen concentration, the second active layer 1406b may have a lower oxygen concentration, and the third active layer 1406c may have an even lower oxygen concentration, thereby forming an oxygen gradient.

For example, the switching stacked arrangement 1406 may be Ta₂O₅/TaO₂/TaO, where the first active layer 1406a includes Ta₂O₅, the second active layer 1406b includes TaO₂, and the third active layer 1406c includes TaO. Through the formation of an oxygen gradient across the layers 1406a-c, the energy barrier for the migration of oxygen ions/vacancies between different layers may be modulated.

The switching stacked arrangement 1406 may be formed of a metal oxide. The metal oxide may include one of Ta oxide, Hf oxide, Zr oxide, Ti oxide, La oxide, and a combination thereof. The oxygen gradient in the switching stacked arrangement 1406 may be obtained by different methods. Suitable methods that may be utilized include physical and chemical techniques. In a more specific example, when sputtering from a Ta target is used, the O/Ta ratio can be controlled through change of the O₂/Ar flow ratio during the reactive sputtering process. The first active layer 1406a may be formed under a higher O₂/Ar flow ratio, the second active layer 1406b may be formed under a lower O₂/Ar flow ratio, and the third active layer 1406c may be formed under an even lower O₂/Ar flow ratio compared to the second active layer 1406b.

The buffer layer 1308, 1408 may be disposed between the first electrode 1302, 1402 and the switching stacked arrangement 1306, 1406. The buffer layer 1308, 1408 may be a material layer having a much larger band gap than the first active layer 1306a, 1406a. In a more specific example, when a Ta oxide is used for the first active layer 1306a, 1406a, the material used for the buffer layer 1308, 1408 may be one of AlOₓ, SiOₓ, MgOₓ, CaOₓ and HfSiOₓ, a combination thereof, or the like, wherein the “x” may refer to any suitable positive number, e.g., 1<x≤1.5 for AlOₓ. Generally speaking, the “x” value may be such that it meets the requirement that the band gap of the buffer layer 1308, 1408 is larger than that of the first active layer 1306a, 1406a. The buffer layer may increase a potential barrier between the first electrode 1302, 1402 and the switching stacked arrangement 1306, 1406.

With the application of a forming voltage, an electroforming process may be needed to be performed on the non-volatile memory device 1300, 1400. The forming process may be performed by applying a voltage to the second electrode 1304, 1404, and the first electrode 1302, 1402 may be grounded. When the current increases to the limit or the compliance current value, the corresponding voltage value applied may be defined as the forming voltage. Through the forming process, conductive paths, such as metal filaments or bridges, may be formed across the buffer layer 1308, 1408 and the switching stacked arrangement 1306, 1406, and the electrical resistance of the device 1300, 1400 may be switched from an initial high resistance state (IRS) to a low resistance state (LRS). The metal filaments or bridges may be formed from oxygen vacancies or metal atom chains.

The first electrode 1302, 1402 may be formed of a metal or a conductive nitride. Examples of materials suitable for the first electrode 1302, 1402 may include W, Al, Cu, Mo, Co, Ni, Fe, Pt, Pd, Au, Ir, Ru, Rh, TiW, TaW, TiN, TaN, and/or other suitable materials. The second electrode 1304, 1404 may be formed of a chemically noble metal or a conductive nitride which is oxidation resistant. For example, the second electrode 1304, 1404 may include at least one of Pt, Pd, Au, Ir, Ru, Rh, TiN and TaN, and/or other suitable materials.

FIG. 15A shows a cross-sectional schematic illustrating an operational mechanism based on the non-volatile memory device 1300 shown in FIG. 13 according to various embodiments. FIG. 15B shows another cross-sectional schematic illustrating the operational mechanism based on the non-volatile memory device 1300 shown in FIG. 13 according to various embodiments. Referring to FIGS. 15A-B, exchange of oxygen ions between the buffer layer 1308 and the switching stacked arrangement 1306 may take place when a voltage or potential difference is applied between the electrodes 1302, 1304. When a positive voltage is applied on the second electrode 1304, oxygen ions move from the buffer layer 1308 to the switching stacked arrangement 1306, and an oxidation process may take place at the switching stacked arrangement 1306. The electrical resistance of the device may change from a low resistance state (LRS, an ON-state) to a high resistance state (HRS, an OFF-state). The voltage value applied to switch the device 1300 from an ON-state to an OFF-state may be defined as the reset voltage. In comparison, when a negative voltage is applied on the second electrode 1304, oxygen ions may move from the switching stacked arrangement 1306 to the buffer layer 1308, and a reduction process may place at the switching stacked arrangement 1306, resulting the electrical resistance of the device 1300 changing from an OFF-state to an ON-state. The voltage value applied to switch from an OFF-state to an ON-state may be defined as the set voltage.

As shown in FIGS. 13 and 14A, a diffusion barrier layer (or ion obstruction barrier layer) 1310, 1410 may be in contact or connection with the switching stacked arrangement 1306, 1406 and the second electrode 1304, 1404. The material used for the diffusion barrier layer 1310, 1410 may be one of IrOₓ, RuOₓ and ITO, a combination thereof, or the like, wherein the “x” may refer to any positive number, e.g., 1<x≤2 for IrOₓ and RuOₓ, respectively. In other words, “x” may be such that 1<x<2 for IrOₓ or RuOₓ. For example, IrOₓ is known as a conductive oxide. It has been used as a diffusion barrier for ions (e.g. oxygen ions and metal ions from the neighboring second electrode 1304, 1404).

FIG. 16A shows a cross-sectional schematic of a non-volatile memory device without an iridium oxide layer. FIG. 16B shows a cross-sectional schematic of a non-volatile memory device with an iridium oxide layer according to various embodiments. FIG. 16A shows a W/Al₂O₃/Ta₂O₅/TaO_{y}/Pt structure. During the switching operation of the device, exchange of oxygen ions at the interface between TaO_{y} and the top electrode Pt may take place, leading to unstable switching operation of the device. For a reliable memory device, controlling the switching at the bottom region (shown in FIGS. 15A-B) may be desired. By the insertion of an IrOₓ layer between TaO_{y} and Pt, FIG. 16B shows a W/Al₂O₃/Ta₂O₅/TaO_{y}/IrOₓ/Pt structure. The IrOₓ layer may work as an oxygen diffusion barrier, and the exchange of oxygen ions at the top interface may be obstructed. When the IrOₓ layer is formed between the TaO_{y} layer and the Pt electrode, Pt may not combine with the underneath Ta oxides. As a result, a stable resistive switching may be achieved.

FIG. 17 shows a plot of current (in Amperes or A) as a function of voltage (in volts or V) illustrating the voltage-current characteristics of the electroforming process of a non-volatile memory device according to various embodiments. FIG. 18 shows a plot of current (in Amperes or A) as a function of voltage (in volts or V) of the non-volatile memory device according to various embodiments after the electroforming process described in FIG. 17. The memory device is a W/Al₂O₃/Ta₂O₅/TaO_{y}/IrOₓ/Ir structure with an arrangement as shown in FIG. 13. The memory device may change from an OFF-state to an ON-state with a negative set voltage applied, and from an ON-state to an OFF-state with a positive reset voltage applied.

FIG. 19 shows a plot of resistance (in ohms or Ω) as a function of cycles illustrating a voltage pulse endurance test results of the non-volatile memory device used for the plots shown in FIGS. 17-18 according to various embodiments. The voltage pulse endurance test is used to determine endurance of a non-volatile memory under high-speed switching operations. The test includes a set voltage pulse to switch the device from an OFF-state to an ON-state, wherein the set voltage pulse has a height of −1.4 V and a pulse width of 200 ns. Sequentially, a reset voltage pulse is applied to switch the device from an ON-state to an OFF-state, wherein the reset voltage pulse has a height of 1.6 V and a pulse width of 200 ns. The voltage pulse endurance test results in FIG. 19 show that the device may be continuously operated, and a stable resistance characteristic may be achieved.

FIG. 20 shows a flow chart of forming a non-volatile memory device according to various embodiments. The method starts from a substrate (Step 2002). A bottom electrode is then formed (Step 2004), followed by the formation of a buffer layer (Step 2006). Step 2008 describes the formation of a switching stacked arrangement, i.e., primary switching layer including multiple layers (n≥2) with an oxygen gradient across the layers. Step 2010 relates to the formation of the diffusion barrier layer, i.e. the ion obstruction barrier layer. Then, the top electrode is formed (Step 2012).

FIG. 21 shows a flow chart of forming a non-volatile memory device according to various embodiments. The method starts from a substrate (Step 2102), and then a bottom electrode is formed (Step 2104), which is followed by the formation of an ion obstruction layer (Step 2106), and a switching stacked arrangement, i.e., primary switching layer including multiple layers (n≥2) with an oxygen gradient across the layers (Step 2108). After this, a buffer layer is formed (Step 2110), and then the formation of the top electrode (Step 2112).

With regard to the flow charts in FIGS. 20-21, the formation of each layer may be carried out by a wide variety of physical and chemical techniques, including sputtering from a target, electron beam evaporation from a crucible, chemical vapor deposition from reactive precursors, and so on. The film thickness may be in the range from 1 to 100 nanometers (nm) for the electrodes, and from 0.5 to 5 nm for the buffer layer, and from 1 to 10 nm for each layer of the switching stacked arrangement and the diffusion barrier layer.

Various embodiments may relate to a non-volatile memory device including a first electrode, a second electrode, a buffer layer, a switching stacked arrangement (i.e., a resistive switching layer) and a diffusion barrier layer (i.e. an ion obstruction barrier layer) disposed between the first electrode and the second electrode. The buffer layer may be physically connected to the first electrode and the switching stacked arrangement. The switching stacked arrangement may be physically connected to the buffer layer and the diffusion barrier layer. The diffusion barrier layer may be physically connected to the switching stacked arrangement and the second electrode. The switching stacked arrangement may include multiple (active) regions or layers. The first (active) region or layer may have high oxygen concentration and physically connected to the buffer layer. The last (active) region or layer may have a low oxygen concentration and physically connected to the diffusion barrier layer. The oxygen concentration may decrease in stages or gradually in a direction from the first region or layer to the last region or layer.

The first electrode may be formed of one of a metal and a conductive nitride. The first electrode may include at least one of W, Al, Cu, Mo, Co, Ni, Fe, Pt, Pd, Au, Ir, Ru, Rh, TiW, TaW, TiN and TaN.

The second electrode may include at least one of Pt, Pd, Au, Ir, Ru, Rh, TiN and TaN.

The buffer layer may be formed of a first metal oxide may include at least one of AlOₓ, SiOₓ, MgOₓ, CaOₓ, HfSiOₓ, and a combination thereof.

The first (active) region or layer may be formed of a second metal oxide. The second metal oxide may include one of Ta oxide, Hf oxide, Zr oxide, Ti oxide, La oxide, and a combination thereof. The first metal oxide may have a band gap greater than the second metal oxide. The second metal oxide may include Ta₂Oₓ, wherein 4.5≤x≤5.

The second (active) region or layer may be formed of a third metal oxide. The oxygen concentration of the second (active) region or layer may be lower than the oxygen concentration of the first (active) region or layer. The third metal oxide may be formed of an oxide from the same group as the second metal oxide. The third metal oxide may be formed of an oxide from the same group as the second metal oxide, but may be doped with a metal element different from the second metal oxide. The third metal oxide may include TaO_{y}, wherein 1≤y≤2.2.

The third (active) region or layer may be formed of a fourth metal oxide. The oxygen concentration of the third (active) region or layer may be lower than the oxygen concentration of the second (active) region or layer.

The fourth metal oxide may be formed of an oxide from the same group as the third metal oxide. The fourth metal oxide may be formed of an oxide from the same group as the third metal oxide, but may be doped with a metal element different from the third metal oxide. The fourth metal oxide may include TaO_{z}, wherein 0<z≤0.5.

The third (active) region or layer may be disposed between the second (active) region or layer and the second electrode.

The diffusion barrier layer may include one or IrOₓ, RuOₓ and ITO.

Each of the first (active) region or layer, the second (active) region or layer, and the third (active) region or layer may have a thickness in a range from 1 nm to 10 nm. The buffer layer may have a thickness in a range from 0.5 nm to 5 nm.

1. A non-volatile memory device comprising:
a first electrode;
a second electrode;
a switching stacked arrangement between the first electrode and the second electrode;
an oxygen scavenger layer between the switching stacked arrangement and the second electrode; and
a diffusion barrier layer between the oxygen scavenger layer and the second electrode;
wherein the switching stacked arrangement comprises alternating tunneling barrier layers and active layers;
wherein a first tunneling barrier layer of the tunneling barrier layers is in physical contact with the first electrode;
wherein a last active layer of the active layers is in physical contact with the oxygen scavenger layer; and
wherein a bandgap of each of the tunneling barrier layers is greater than a bandgap of each of the active layers.

2. The non-volatile memory device according to claim 1, wherein the diffusion barrier layer comprises one or more materials selected from a group consisting of tantalum, titanium, hafnium, zirconium, iridium oxide, ruthenium oxide and indium tin oxide.

3. The non-volatile memory device according to claim 1, wherein the diffusion barrier layer has a thickness selected from a range from 1 nm to 10 nm.

4. The non-volatile memory device according to claim 1,
wherein the tunneling barrier layers comprise a first material; and
wherein the active layers comprise a second material different from the first material.

5. The non-volatile memory device according to claim 4, wherein an interatomic bonding energy of the first material is greater than an interatomic bonding energy of the second material.

6. The non-volatile memory device according to claim 1,
wherein the tunneling barrier layers comprise a first metal oxide; and
wherein the active layers comprise a second metal oxide different from the first metal oxide.

7. The non-volatile memory device according to claim 1, wherein the tunneling barrier layers comprise a material selected from a group consisting of aluminum oxide, silicon oxide, magnesium oxide, calcium oxide, hafnium silicate and any combination thereof.

8. The non-volatile memory device according to claim 1, wherein the active layers comprise a material selected from a group consisting of tantalum oxide, hafnium oxide, zirconium oxide, titanium oxide, lanthanum oxide and any combination thereof.

9. The non-volatile memory device according to claim 1, wherein the tunneling barrier layers are more stable than the active layers.

10. The non-volatile memory device according to claim 1, wherein the first electrode comprises a metal or a conductive nitride.

11. The non-volatile memory device according to claim 1, wherein the first electrode comprises one or more materials selected from a group consisting of tungsten (W), aluminum (Al), copper (Cu), molybdenum (Mo), cobalt (Co), nickel (Ni), iron (Fe), platinum (Pt), palladium (Pd), gold (Au), iridium (Ir), ruthenium (Ru), rhodium (Rh), titanium tungsten (TiW), tantalum tungsten (TaW), titanium nitride (TiN) and tantalum nitride (TaN).

12. The non-volatile memory device according to claim 1, wherein the second electrode comprises a metal or a conductive nitride.

13. The non-volatile memory device according to claim 1, wherein the second electrode comprises one or more materials selected from a group consisting of platinum (Pt), palladium (Pd), gold (Au), iridium (Ir), ruthenium (Ru), rhodium (Rh), titanium nitride (TiN) and tantalum nitride (TaN).

14. The non-volatile memory device according to claim 1, wherein an oxygen concentration layer of the oxygen scavenger layer is lower than an oxygen concentration layer of the last active layer.

15. The non-volatile memory device according to claim 1, wherein the oxygen scavenger layer comprises a metal oxide.

16. The non-volatile memory device according to claim 1, further comprising:
a further oxygen scavenger layer between the oxygen scavenger layer and the diffusion layer;
wherein an oxygen concentration layer of the further oxygen scavenger layer is lower than the oxygen scavenger layer.

17. The non-volatile memory device according to claim 1, wherein the oxygen scavenger layer comprises TaO_{z}, wherein 0<z<1.

18. The non-volatile memory device according to claim 1, wherein each of the tunneling barrier layers has a thickness selected from a range from 0.5 nm to 1.5 nm.

19. The non-volatile memory device according to claim 1, wherein each of the active layers has a thickness selected from a range from 1 nm to 3 nm.

20. A method of forming a non-volatile memory device, the method comprising:
forming a first electrode;
forming a second electrode;
forming a switching stacked arrangement between the first electrode and the second electrode;
forming an oxygen scavenger layer between the switching stacked arrangement and the second electrode; and
forming a diffusion barrier layer between the oxygen scavenger layer and the second electrode;
wherein the switching stacked arrangement comprises alternating tunneling barrier layers and active layers;
wherein a first tunneling barrier layer of the tunneling barrier layers is in physical contact with the first electrode;
wherein a last active layer of the active layers is in physical contact with the oxygen scavenger layer; and
wherein a bandgap of the tunneling barrier layers is greater than a bandgap of the active layers.

21-22. (canceled)
